(19) United States
(12) Patent Application Publication
(10) Pub. No.: US 2026/0255539 A1
(43) Pub. Date: Aug. 27, 2026

(54) DUO-PUMP LIQUID COOLING DEVICE

(71) Applicant: SHENZHEN APALTEK CO., LTD., Shenzhen (CN)

(72) Inventors: Qineng XIAO, Dongguan (CN); Dagao ZHENG, Shenzhen (CN); Dabiao LING, Shenzhen (CN)

(21) Appl. No.: 19/294,876

(22) Filed: Aug. 8, 2025

(30) Foreign Application Priority Data
Feb. 27, 2025 (CN) 2025102281934

(51) Int. Cl. H05K 7/20; F04D 13/12

(52) U.S. Cl. CPC H05K 7/20272; F04D 13/12

(57) ABSTRACT

A duo-pump liquid cooling device having a base seat, two pumps, a separating assembly, and a bottom seat is provided. The base seat has an inlet port, an outlet port, two accommodated grooves for arranging the pumps, a concentrated cavity communicated to the inlet port and the accommodated grooves, two channels communicated to the accommodated grooves, and an outlet groove communicated to the outlet port. The separating assembly has two through hole groups, two diversion grooves, a through slot group communicated to the through hole groups, and a penetration hole. A heat exchange chamber and two reflux cavities are formed between the separating assembly and the bottom seat. The heat exchange chamber is communicated to the channels through the through hole groups, the diversion grooves, and the through slot group and the outlet groove. The duo-pump liquid cooling device is therefore increasing coolant flow and improving heat dissipation efficiency.

### BACKGROUND

### Technical Field

The present disclosure relates to the field of liquid cooling, particularly to a duo-pump liquid cooling device.

### Description of Related Art

In a liquid cooling system, a coolant is sealed and filled in a closed loop to flow cyclically, and the coolant is used as a medium to carry a heat from a heat source to a heat dissipator for cooling and heat dissipation. Therefore, most liquid cooling systems use a pump to make the coolant to flow, and a heat dissipation efficiency of the entire liquid cooling system is better when a flow rate of the coolant is faster.

As electronic technology develops towards thinner and more powerful, the heat generated thereof has also increased significantly. However, the heat dissipator with single pump may only drive a limited flow rate of the coolant such that the heat dissipation efficiency thereof is insufficient. In addition, in order to cope with the thinner design, a capacity of the coolant may be reduced when the overall volume of the liquid cooling system is reduced. Therefore, after a period of use, the coolant would not be sufficient due to evaporation or leakage to affect the operation of the liquid cooling system.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to increase the flow rate of the coolant in the duo-pump liquid cooling device to improve heat dissipation efficiency, prevent the coolant from becoming insufficient due to evaporation or leakage after a period of use, improve the sealing of the base seat, and reduce assembly complexity and maintenance costs.

To accomplish the aforementioned objective, the present disclosure provides a duo-pump liquid cooling device having a base seat, a pair of pumps, a separating assembly, and a bottom seat. The base seat has an inlet port, an outlet port, a concentrated cavity, a pair of accommodated grooves, a pair of channels, and an outlet groove. The inlet port is communicated to the concentrated cavity. The outlet port is communicated to the outlet groove. Each of the accommodated grooves is arranged in parallel and communicated to the concentrated cavity. Each of the channels is communicated to each of the accommodated grooves and located on two sides of the concentrated cavity. The pumps are respectively configured to correspond to each of the accommodated grooves. The concentrated cavity is located between the separating assembly and each of the accommodated grooves. The separating assembly covers the concentrated cavity and has a pair of through hole groups, a pair of diversion grooves, a through slot group, and a penetration hole. Each of the through hole groups is communicated to the through slot group through each of the diversion grooves. The base seat is arranged on the bottom seat to form a heat exchange chamber and a pair of reflux cavities between the separating assembly and the bottom seat. Each of the channels is communicated to the heat exchange chamber sequentially through each of the through hole groups, each of the diversion grooves, and the through slot group. The heat exchange chamber is communicated to each of the reflux cavities and communicated to the outlet groove through the penetration hole.

Another aspect of the present disclosure provides that the bottom seat has a plurality of fins arranged in parallel, a plurality of flow channels is formed between each two of the fins, each of the fins and the separating assembly together separate the heat exchange chamber to each of the flow channels and a pair of confluence areas, two ends of each of the flow channels are communicated to each of the reflux cavities through each of the confluence areas.

Another aspect of the present disclosure provides that each of the through hole groups is configured to be located at a diagonal corner the separating assembly.

Another aspect of the present disclosure provides that a location of the through slot group is located at a center of each of the fins.

Another aspect of the present disclosure provides that the separating assembly includes a separating plate and a diversion plate, the separating plate is arranged between the base seat and the diversion plate and has each of the through hole groups, the diversion plate has each of the diversion grooves and is located between each of the through hole groups.

Another aspect of the present disclosure provides that the separating plate includes a first partition plate and a second partition plate, the second partition plate is arranged between the first partition plate and the diversion plate, the penetration hole is defined on the first partition plate, a reflux gap is formed between the first partition plate and the second partition plate, each of the reflux cavities is communicated to the penetration hole through the reflux gap.

Another aspect of the present disclosure provides that the separating assembly further includes an abutting sheet, the abutting sheet is arranged between the diversion plate and the bottom seat, the abutting sheet has a pair of limiting baffles, each of the limiting baffles is limited on two opposite sides of the diversion plate.

Another aspect of the present disclosure provides that the base seat includes a main body and a mounting frame, the main body has the inlet port, the outlet port, the concentrated cavity, each of the accommodated grooves, each of the channels, and the outlet groove, the mounting frame has a pair of mounting grooves, is arranged on the main body, and covers each of the accommodated grooves, each of the mounting grooves is configured to correspond to each of the accommodated grooves.

Another aspect of the present disclosure provides that each of the pumps includes a stator assembly and a rotor assembly, each of the rotor assemblies is arranged in each of the accommodated grooves, each of the stator assemblies is arranged in each of the mounting grooves.

Another aspect of the present disclosure provides that the inlet port and the outlet port are located on same side of the base seat.

In the duo-pump liquid cooling device of the present disclosure, the base seat forms the concentrated cavity, and the pumps are arranged in the accommodated grooves of the base seat in parallel. Therefore, the coolant may converge in the concentrated cavity after entering from the inlet port, and then the coolant sequentially enters the accommodated grooves, the channels, the through hole groups, the diversion grooves, the through slot group, and the heat exchange chamber by a suction force generated by the pumps when they are running. The duo-pump liquid cooling device of the present disclosure is therefore increasing the flow rate of the coolant therein to improve heat dissipation efficiency, preventing the coolant from becoming insufficient due to evaporation or leakage after a period of use, improving the sealing of the base seat, and reducing assembly complexity and maintenance costs. In addition, the coolant may sequentially enter the reflux cavities, the penetration hole, and the outlet groove from the heat exchange chamber, so as to prevent the coolant from directly impacting upward to the separator assembly while refluxing.

### BRIEF DESCRIPTION OF THE DRAWINGS

FIG. 1 is an exploded view of the present disclosure;

FIG. 2 is another exploded view of the present disclosure;

FIG. 3 is a perspective appearance view of the present disclosure;

FIG. 4 is a cross-sectional front view of the present disclosure;

FIG. 5 is a cross-sectional view along A-A of FIG. 4;

FIG. 6 is a cross-sectional view along B-B of FIG. 4;

FIG. 7 is a cross-sectional top view of the concentrated cavity and the outlet groove of the present disclosure;

FIG. 8 is a cross-sectional view along C-C of FIG. 4; and

FIG. 9 is a cross-sectional view along D-D of FIG. 4.

### DETAILED DESCRIPTION

It is to be understood that the terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used for separating the element, the assembly, the area, the layer, or the part. Unless being clearly indicated according to the whole specification, the terms for example “the first”, “the second”, “the third”, “the fourth” and “the fifth” are not used for implying the order or sequence.

As used herein and not otherwise defined, the terms "substantially" and "approximately" are used to describe and describe small changes. When used in connection with an event or situation, the terms may include the precise moment at which the event or situation occurs, as well as the event or situation occurring to a close approximation. For example, when combined with a numerical value, the terms may include a range of variation equal to or less than ±5% of the numerical value, such as equal to or less than ±4%, equal to or less than ±3%, equal to or less than ±2%, equal to or less than ±1%, equal to or less than ±0.5%, equal to or less than ±0.1%, or equal to or less than ±0.05%.

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

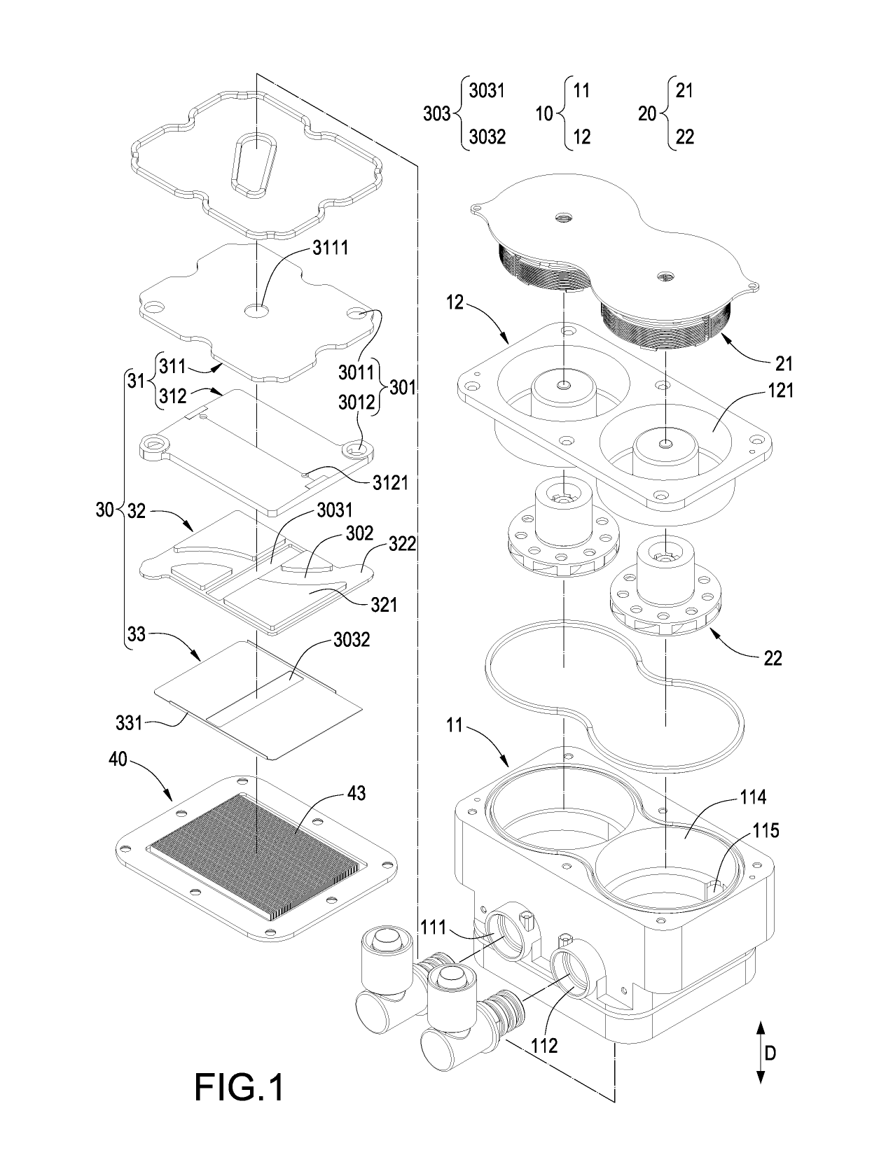

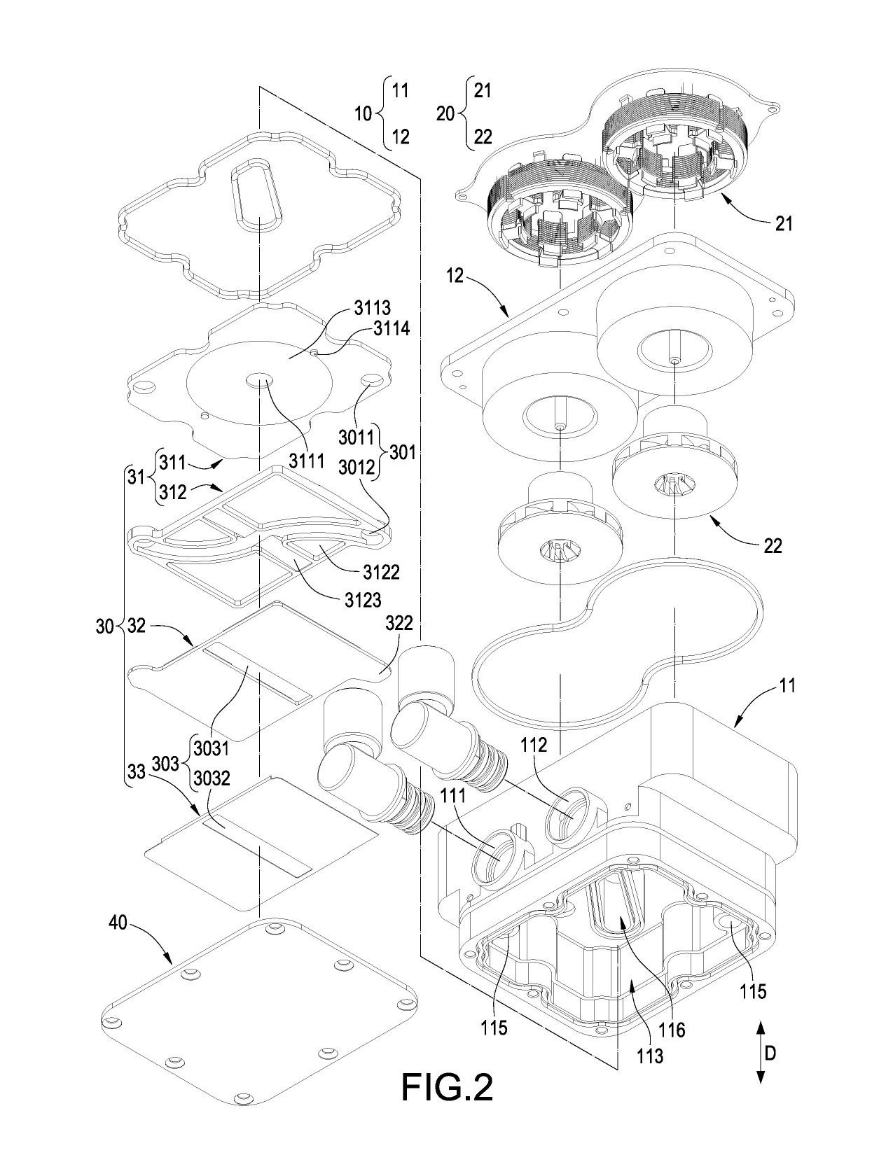

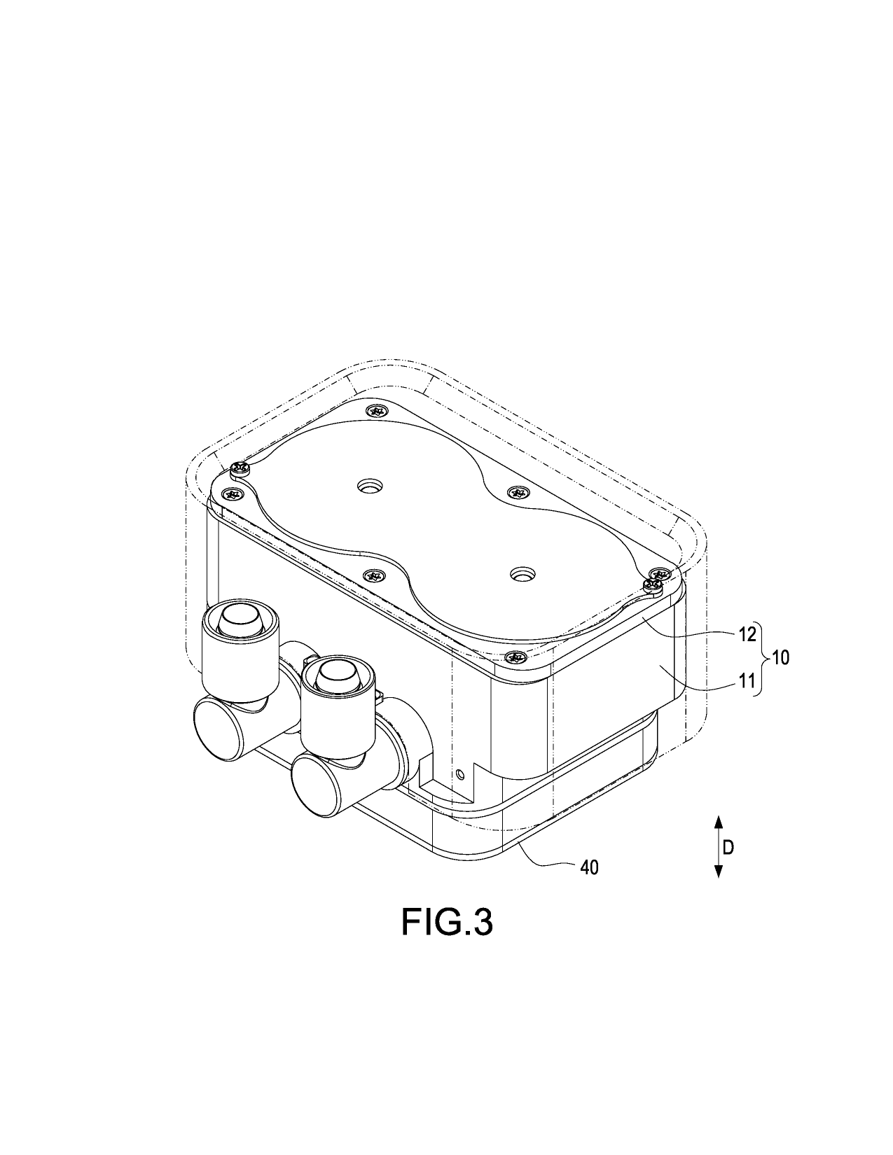

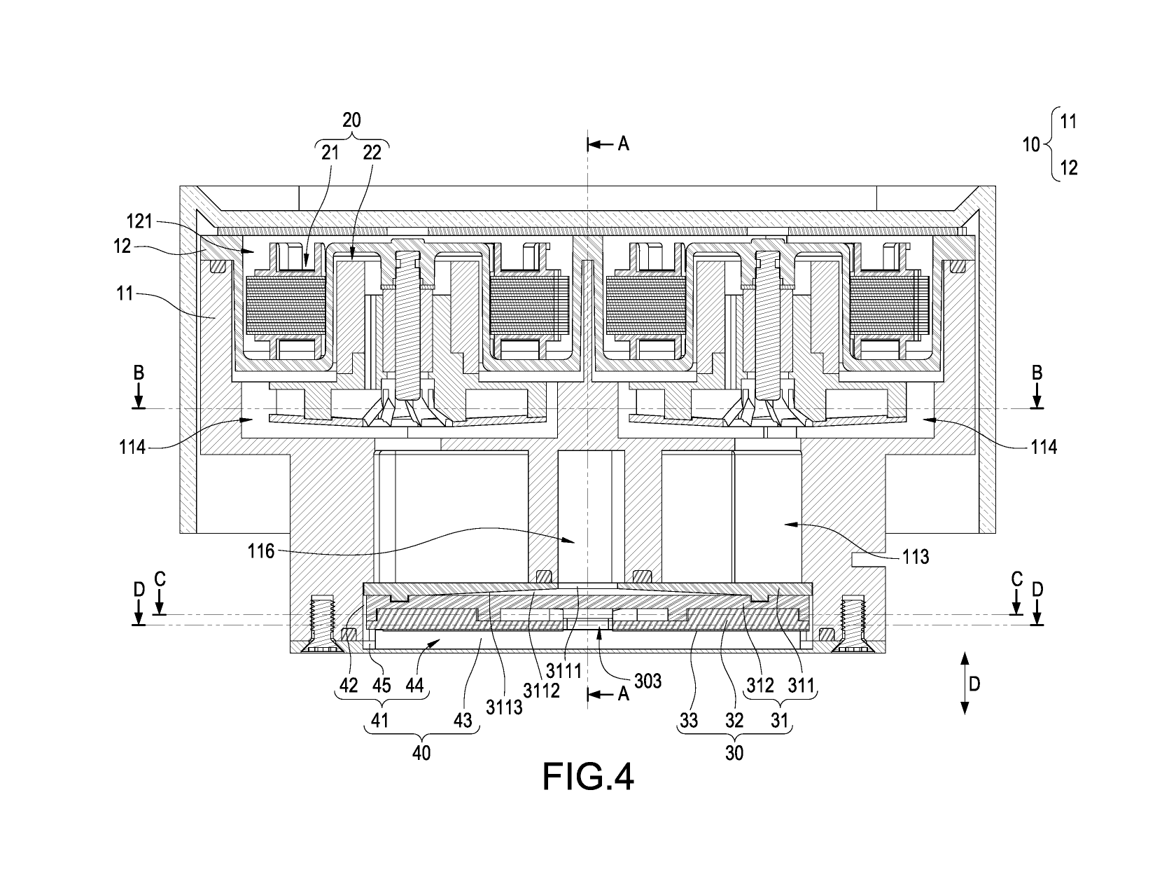

The present disclosure provides a duo-pump liquid cooling device for a coolant to flow through. Please refer to FIG. 1, FIG. 2, FIG. 3, and FIG. 4, the duo-pump liquid cooling device of the present disclosure includes a base seat 10, a pair of pumps 20, a separating assembly 30, and a bottom seat 40.

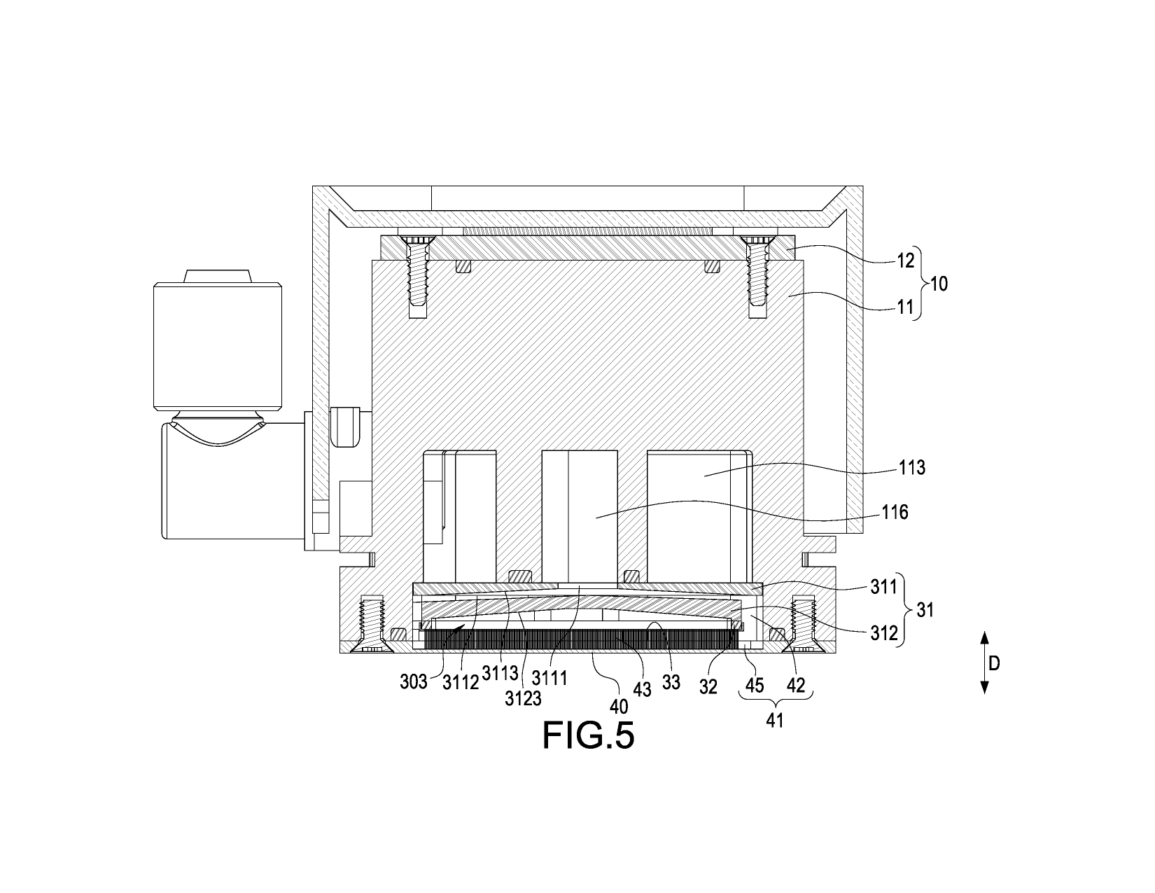

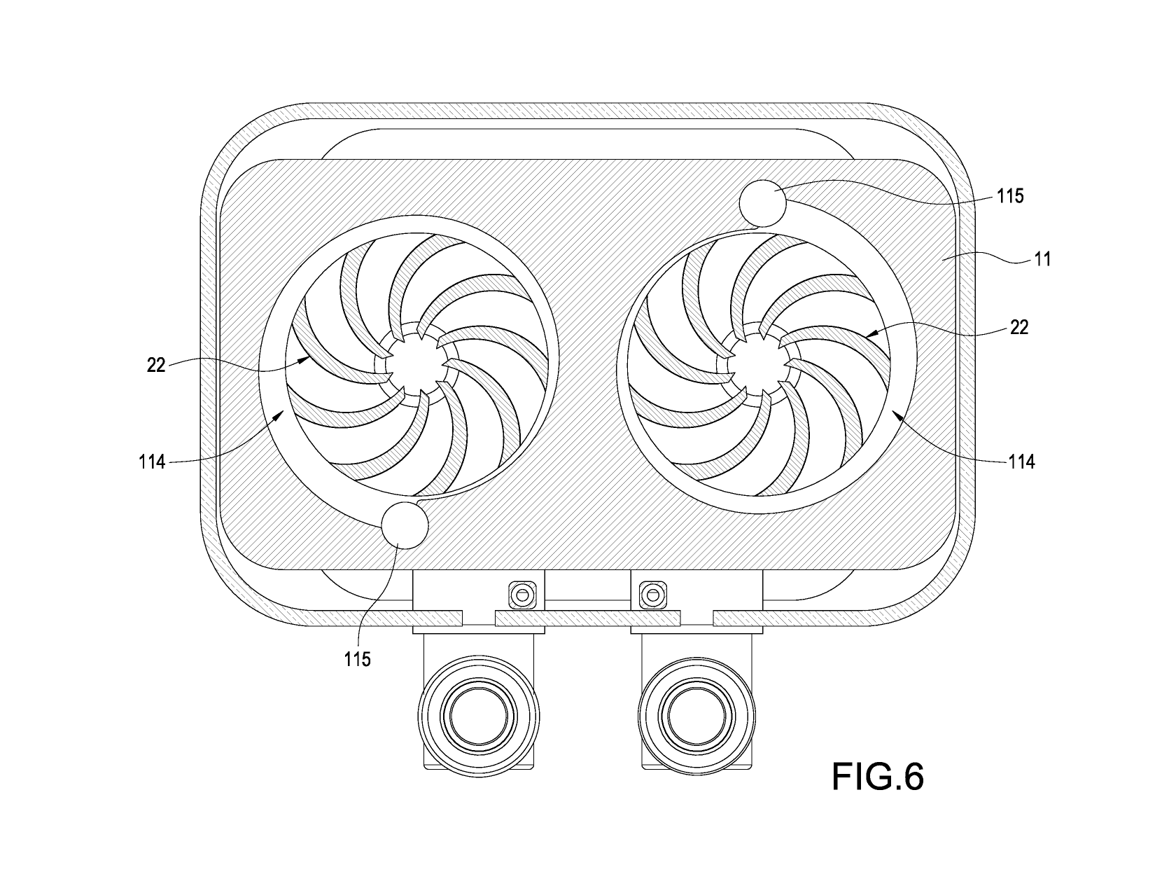

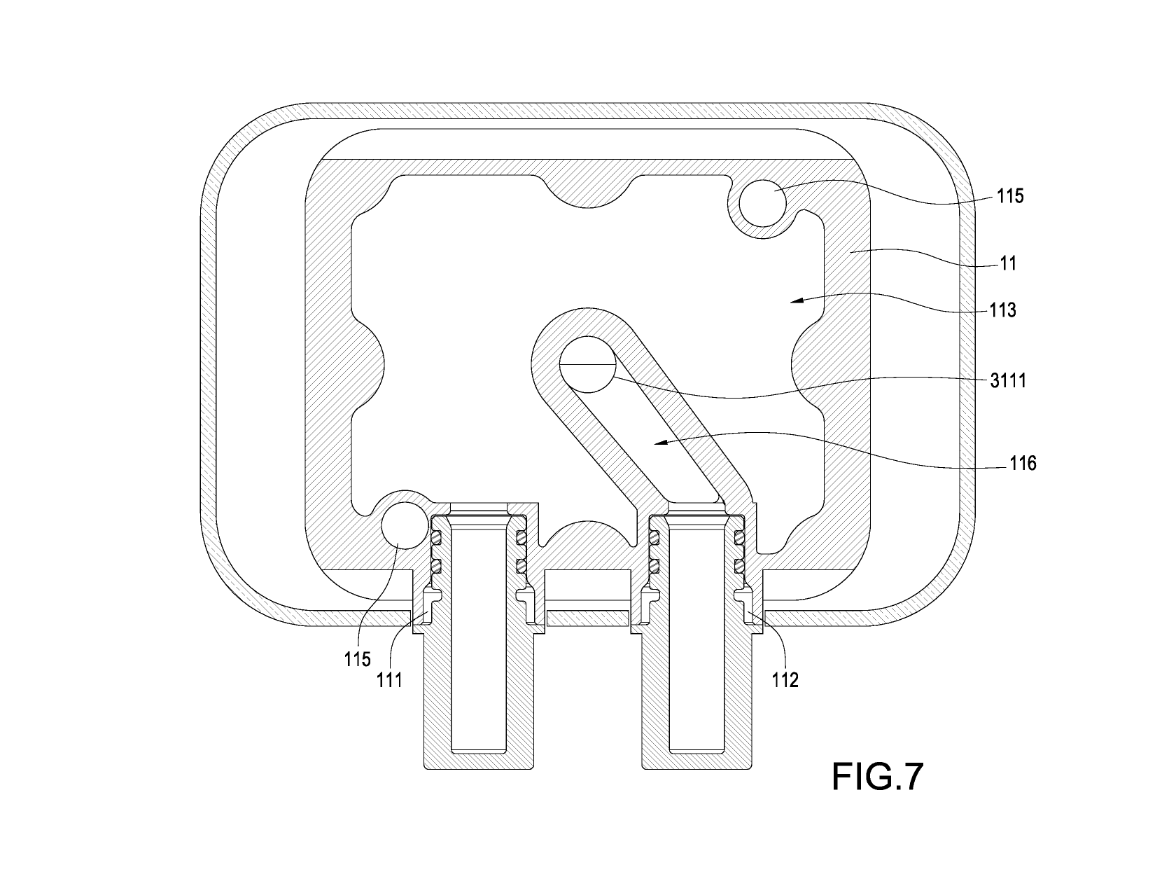

The base seat 10 is arranged on the bottom seat 40 along an up-down direction D. In the embodiment, the base seat 10 is rectangular, but the present disclosure is not limited to this embodiment. The base seat 10 has an inlet port 111, an outlet port 112, a concentrated cavity 113, a pair of accommodated grooves 114, a pair of channels 115, and an outlet groove 116. In the embodiment, the inlet port 111 and the outlet port 112 are both located on the same side of the base seat 10 such that a pair of infusion tubes (not shown in figures) respectively connected to the inlet port 111 and the outlet port 112 may be easily organized, but the inlet port 111 and the outlet port 112 may also be located on the different sides of the base seat 10 in other embodiments. Please refer to FIG. 1, FIG. 4, FIG. 5, FIG. 6, and FIG. 7, the inlet port 111 is communicated to the concentrated cavity 113, and the outlet port 112 is communicated to the outlet groove 116. In detail, the concentrated cavity 113 and the outlet groove 116 are both formed on a bottom of the base seat 10, and the concentrated cavity 113 and the outlet groove 116 are not directly communicated to each other. Please refer to FIG. 1, FIG. 4, FIG. 5, and FIG. 6, each of the accommodated grooves 114 is arranged on a top of the base seat 10 in parallel and respectively communicated to the concentrated cavity 113. In other words, each of the accommodated grooves 114 is located on the concentrated cavity 113 along the up-down direction D, and the inlet port 111 may be communicated to each of the accommodated grooves 114 through the concentrated cavity 113, as shown in FIG. 6 and FIG. 7. Each of the channels 115 is configured to be corresponding to each of the accommodated grooves 114, communicated to each of the accommodated grooves 114, and located on two sides of the concentrated cavity 113. In the embodiment, the channels 115 are located at a diagonal position of the concentrated cavity 113, and each of the channels 115 is extended along the up-down direction D inward the base seat 10, but the present disclosure is not limited to this embodiment. For example, the channels 115 may also be oppositely located on two sides of the concentrated cavity 113, or each of the channels 115 may also be extended to be tilted relative to the up-down direction D in the base seat 10.

Please refer to FIG. 1, FIG. 2, FIG. 3, FIG. 4, and FIG. 6, each of the pumps 20 is configured to correspond to each of the accommodated grooves 114. In detail, the base seat 10 includes a main body 11 and a mounting frame 12. The main body 11 is in a one-piece form, and the main body 11 has the inlet port 111, the outlet port 112, the concentrated cavity 113, the accommodated grooves 114, the channels 115, and the outlet groove 116. The mounting frame 12 has a pair of mounting grooves 121. The mounting frame 12 is arranged on a top of the main body 11 and covers each of the accommodated grooves 114, such that each of the mounting grooves 121 is configured to correspond to each of the accommodated grooves 114. In other words, the mounting grooves 121 and the accommodated grooves 114 are respectively located on two opposite sides of the mounting frame 12. Each of the pumps 20 includes a stator assembly 21 and a rotor assembly 22. Each of the rotor assemblies 22 is arranged in each of the accommodated grooves 114, and each of the stator assemblies 21 is arranged in each of the mounting grooves 121. In other words, each of the stator assemblies 21 is located on the corresponding rotor assembly 22 along the up-down direction D and surrounds a part of the corresponding rotor assembly 22. Since the specific structure and operation principle of the pumps 20 are well known in the art, they are not be described in detail.

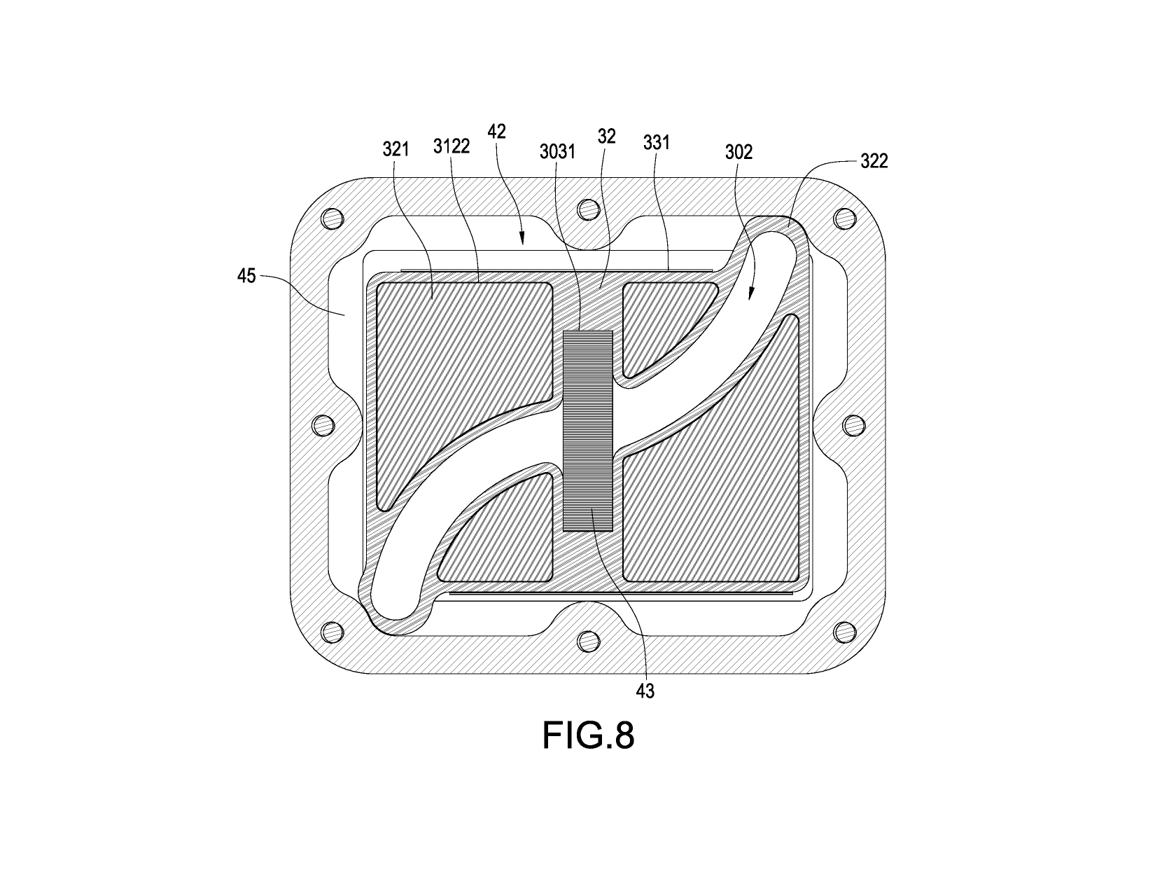

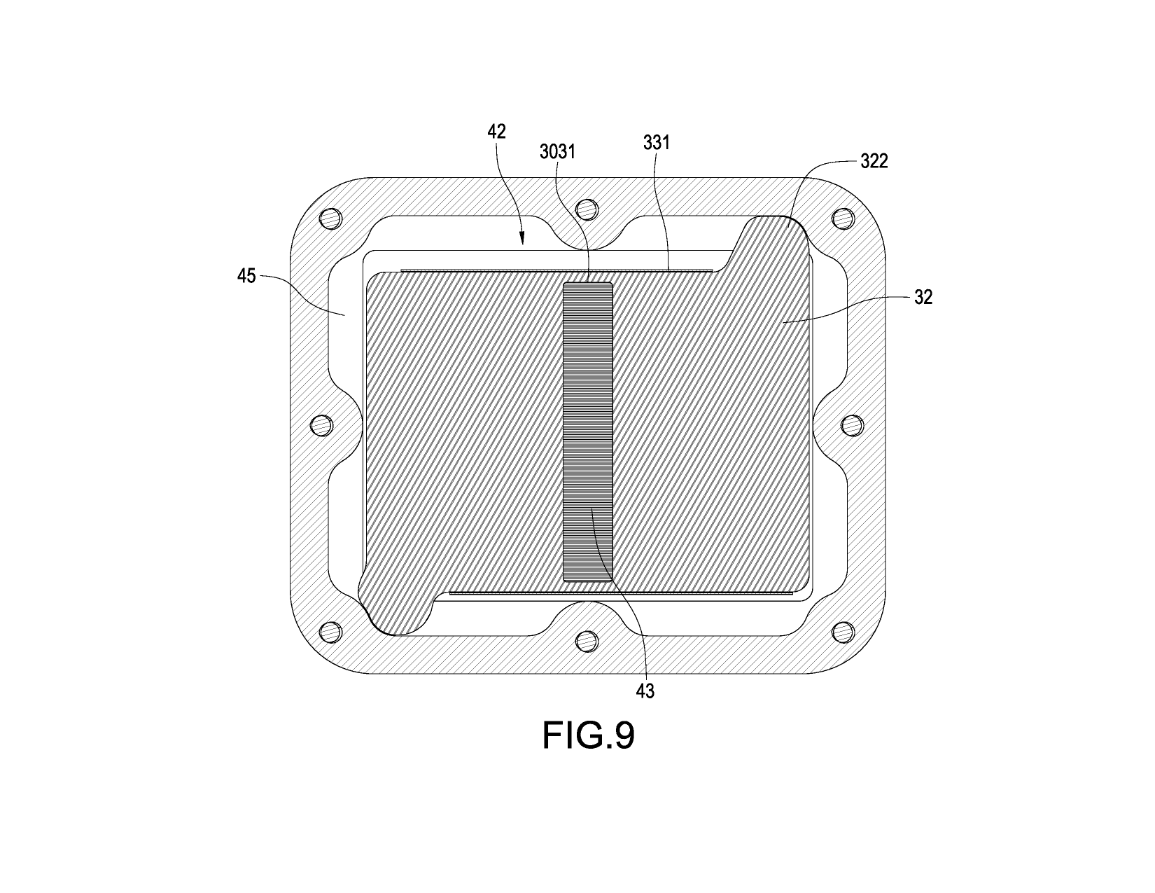

Please refer to FIG. 1, FIG. 2, FIG. 3, FIG. 4, FIG. 5, FIG. 8, and FIG. 9, the separating assembly 30 covers a bottom of the concentrated cavity 113. In detail, the separating assembly 30 is abutted against between the bottom seat 40 and the base seat 10, such that the concentrated cavity 113 is substantially located between the separating assembly 30 and each of the accommodated grooves 114. The separating assembly 30 has a pair of through hole groups 301, a pair of diversion grooves 302, a through slot group 303, and a penetration hole 3111. A heat exchange chamber 41 and a pair of reflux cavities 42 are formed between the separating assembly 30 and the bottom seat 40. The through hole groups 301 are respectively communicated to the through slot group 303 though the diversion grooves 302, such that each of the channels 115 is communicated to the heat exchange chamber 41 sequentially through each of the through hole groups 301, each of the diversion grooves 302, and the through slot group 303. The heat exchange chamber 41 is communicated to the reflux cavities 42 and communicated to the outlet groove 116 through the penetration hole 3111. Therefore, the coolant may converge in the concentrated cavity 113 of the base seat 10 after the coolant entering the inlet port 111, and then the coolant is absorbed to the accommodated grooves 114 by a suction force generated by the pumps 20 when they are running. The coolant sequentially enters the heat exchange chamber 41 sequentially through the channels 115, the through hole groups 301, the diversion grooves 302, the through slot group 303, enters the outlet groove 116 of the base seat 10 sequentially through the reflux cavities 42 and the penetration hole 3111, and finally leaves the outlet port 112. Therefore, the arrangement of the concentrated cavity 113 may increase the flow rate of the coolant in the duo-pump liquid cooling device of the present disclosure to improve heat dissipation efficiency and prevent the coolant from becoming insufficient due to evaporation or leakage after a period of use. In addition, since the main body 11 of the base seat 10 is in a one-piece form instead of two parts form, the coolant is therefore avoiding leakage from a seam between the two parts to improve sealing and reduce assembly complexity and maintenance costs. Furthermore, the diversion grooves 302 of the separator assembly 30 may guide the coolant to converge in the through slot group 303 to enter the heat exchange chamber 41, and then the coolant refluxes from the reflux cavities 42 located on two sides of the heat exchange chamber 41 to enter the outlet groove 116, such that the coolant may be concentrated into the heat exchange chamber 41 to dissipate heat and be prevented from directly impacting upward to the separator assembly 30 while refluxing.

Details are provided as follows. The bottom seat 40 has a plurality of fins 43 arranged in parallel. Each of the fins 43 is arranged on a side of the bottom seat 40 facing the base seat 10 and the separating assembly 30, that is each of the fins 43 is arranged on a top of the bottom seat 40. A plurality of flow channels 44 parallel to each other is formed between each two of the fins 43. Each of the flow channels 44 is communicated to the through slot group 303 of the separating assembly 30, and two ends of each of the flow channels 44 are communicated to the penetration hole 3111 through the reflux cavities 42 to be communicated to the outlet groove 116 of the base seat 10. In detail, the fins 43 and a part of the separating assembly 30 together separate the heat exchange chamber 41 to the flow channels 44 and a pair of confluence areas 45. Two ends of each of the flow channels 44 are respectively communicated to each of the reflux cavities 42 through each of the confluence areas 45, that is the fins 43 and the flow channels 44 are all located between the confluence areas 45. The through hole group 301 are respectively communicated to the flow channels 44 sequentially through the diversion grooves 302 and the through slot group 303. In the embodiment, the through hole groups 301 are located at a diagonal position of the fins 43, and the through slot group 303 is located at a center of the fins 43. Therefore, the coolant may converge at the through slot group 303 from the through hole groups 301 located on the diagonal position of the fins 43 to enter a center of the flow channels 44, but the present disclosure is not limited to this embodiment. Therefore, when the coolant enters the heat exchange chamber 41 through the through slot group 303, the coolant may evenly shunt from the center of the flow channels 44, and then the coolant evenly enters the reflux cavities 42 from the confluence areas 45 to leave the heat exchange chamber 41, so as to improve heat dissipation efficiency of the center of the fins 43 and ensure that the coolant may evenly flow in each of the flow channels 44.

Please refer to FIG. 1, FIG. 2, FIG. 4, FIG. 5, FIG. 8, and FIG. 9, the separating assembly 30 includes a separating plate 31, a diversion plate 32, and an abutting sheet 33. In the embodiment, the separating plate 31 and the abutting sheet 33 are both made of metal, the diversion plate 32 is made of silicone or rubber, but the present disclosure is not limited to this embodiment. The separating plate 31 is abutted against and arranged between the base seat 10 and the diversion plate 32, and the separating plate 31 has the through hole groups 301 and the penetration hole 3111. The diversion plate 32 is abutted against and arranged between the abutting sheet 33 and the separating plate 31. The diversion plate 32 has the diversion grooves 302 and is located among the through hole groups 301, the confluence areas 45, and the reflux cavities 42. In other words, the abutting sheet 33 is arranged between the diversion plate 32 and the fins 43 of the bottom seat 40. Therefore, the abutting sheet 33, the diversion plate 32, and the separating plate 31 of the separating assembly 30 are sequentially stacked on the bottom seat 40 along the up-down direction D.

Details are provided as follows. The separating plate 31 has a first partition plate 311 and a second partition plate 312. The second partition plate 312 is arranged between the first partition plate 311 and the diversion plate 32. The penetration hole 3111 is defined on the first partition plate 311. In the embodiment, the penetration hole 3111 is located on a center of the first partition plate 311, but the present disclosure is not limited to this embodiment. A reflux gap 3112 is formed between the first partition plate 311 and the second partition plate 312, such that the reflux cavities 42 may be communicated to the penetration hole 3111 through the reflux gap 3112. In addition, the first partition plate 311 has an inclined groove 3113. In detail, the inclined groove 3113 is defined on a side of the first partition plate 311 facing the second partition plate 312 (that is a bottom surface of the first partition plate 311), and the inclined groove 3113 is concave from the bottom surface of the first partition plate 311 and obliquely extended toward the penetration hole 3111. In other words, the penetration hole 3111 is located at a center of the inclined groove 3113, and the inclined groove 3113 is obliquely concave from the bottom surface of the first partition plate 311 toward the penetration hole 3111. A volume of the reflux gap 3112 is therefore efficiently increasing, such that the coolant may smoothly flow through the penetration hole 3111 without blockage to enter the outlet groove 116 of the base seat 10 when the coolant enters the reflux gap 3112 from the reflux cavities 42. Therefore, when the coolant flows into the reflux cavities 42 from the confluence areas 45 located on two sides of the flow channels 44, the coolant may enter the reflux gap 3112 between the first partition plate 311 and the second partition plate 312 from the reflux cavities 42 located on two sides of the partition assembly 30, and finally leave the separating assembly 30 from the penetration hole 3111 of the first partition plate 311 to the outlet port 116 of the base 10, so as to prevent the coolant from directly impacting the separating assembly 30 from bottom to top along the up-down direction D in the heat exchange chamber 41 and effectively improve the stability of the overall structure.

In addition, the first partition plate 311 has a positioning block 3114, and the second partition plate 312 has a positioning hole 3121. The positioning block 3114 is fixed in the positioning hole 3121 to position the first partition plate 311 and the second partition plate 312, so as to position them and prevent them from relative displacement, but the present disclosure is not limited to this embodiment. For example, in another embodiment, the positioning block 3114 may also be arranged on the second partition plate 312, and the positioning hole 3121 may also be arranged on the first partition plate 311. Each of the through hole groups 301 in the embodiment includes a first through hole 3011 and a second through hole 3012. In each of the through hole groups 301, the first through hole 3011 passes through the first partition plate 311, and the second through hole 3012 is corresponding to the first through hole 3011 and passes through the second partition plate 312 such that the first through hole 3011 is communicated to the second through hole 3012. In other words, each of the channels 115 is sequentially communicated to the first through hole 3011 and the second through hole 3012 of the corresponding through hole groups 301 and the corresponding diversion groove 302.

Details are provided as follows. The second partition plate 312 has a plurality of embedded grooves 3112, and the diversion plate 32 has a plurality of embedded blocks 321. In detail, the embedded grooves 3112 are concave from the second partition plate 312 facing the diversion plate 32 (that is a bottom surface of the second partition plate 312) upward, and the embedded blocks 321 is extended from a side of the diversion plate 32 facing the second partition plate 312 (that is a top surface of the diversion plate 32). The embedded blocks 321 are fixed to the embedded grooves 3112 to position the diversion plate 32 to the second partition plate 312, so as to position them and prevent them from relative displacement. In the embodiment, a number of the embedded groove 3112 and a number of the embedded block 321 are both four, the through slot group 303 and the diversion grooves 302 are formed between four embedded grooves 3112 and four embedded blocks 321, but the number of the embedded groove 3112 and the number of the embedded block 321 are not limited to this embodiment. In detail, the through slot group 303 includes a first through slot 3031 and a second through slot 3032. The first through slot 3031 passes through the diversion plate 32, and the second through slot 3032 is corresponding to the first through slot 3031 and passes through the abutting sheet 33 to be communicated to the first through slot 3031. Therefore, in the embodiment, the first through slot 3031 is located at a center of the diversion plate 32 and between the embedded blocks 321 and the embedded grooves 3112, the diversion grooves 302 is formed between the second partition plate 312 and the diversion plate 32 and located between the embedded blocks 321 and the embedded grooves 3112. In the embodiment, a convex arm 322 is extended horizontally from a position of the diversion plate 32 corresponding to the through hole groups 301, such that the coolant will be stopped by the convex arms 322 after passing through the through hole groups 301 along the up-down direction D and may only flow along the diversion grooves 302 to the through slot group 303 of the center of the diversion grooves 302. In the embodiment, a pair of guiding slopes 3123 are formed on a position of the bottom surface of the second partition plate 312 corresponding to the through slot group 303. The guiding slopes 3123 are corresponding to the through slot group 303 and obliquely concave from the bottom of the second partition plate 312 toward an intersection of the diversion grooves 302, so as to efficiently increase volume for the coolant smoothly flowing through the through slot group 303 without blockage, but the present disclosure is not limited to this embodiment. In addition, the abutting sheet 33 has a pair of limiting baffles 331. The limiting baffles 331 limit two opposite sides of the diversion plate 32 to position the abutting sheet 33 to the diversion plate 32.

It is worth noting that the through slot group 303 of the separating assembly 30 is substantially perpendicular to each of the fins 43 and each of the flow channels 44, and the through slot group 303 is approximately located at a center of each of the fins 43 and each of the flow channels 44. In detail, please refer to FIG. 1, FIG. 2, FIG. 3, FIG. 4, FIG. 5, and FIG. 8 for example. Each of the fins 43 and each of the flow channels 44 is perpendicular to a front-rear direction (a defined direction of the inlet port 111 and the outlet port 112) of the base seat 10 and the bottom seat 40, and the first through slot 3031 and the second through slot 3032 of the through slot group 303 are substantially parallel to a left-right direction of the base seat 10 and the bottom seat 40 such that the first through slot 3031 and the second through slot 3032 are both perpendicular to each of the fins 43 and each of the flow channels 44. Therefore, after the coolant enters the through slot group 303 from the diversion grooves 302, the coolant evenly flows from a center of the fins 43 and the flow channels 44 toward two sides to enter the confluence areas 45, and then the coolant passes through the reflux cavities 42 to enter the reflux gap 3112 and leave the separating assembly 30 from the penetration hole 3111 to enter the outlet groove 116 of the base seat 10.

In the duo-pump liquid cooling device of the present disclosure, the base seat 10 forms the concentrated cavity 113, and the pumps 20 are arranged in the accommodated grooves 114 of the base seat 10 in parallel. Therefore, the coolant may converge in the concentrated cavity 113 after entering from the inlet port 111, and then the coolant sequentially enters the accommodated grooves 114, the channels 115, the through hole groups 301, the diversion grooves 302, the through slot group 303, and the heat exchange chamber 41 by a suction force generated by the pumps 20 when they are running. The duo-pump liquid cooling device of the present disclosure is therefore increasing the flow rate of the coolant therein to improve heat dissipation efficiency, preventing the coolant from becoming insufficient due to evaporation or leakage after a period of use, improving the sealing of the base seat 10, and reducing assembly complexity and maintenance costs. In addition, the coolant may sequentially enter the reflux cavities 42, the penetration hole 3111, and the outlet groove 116 from the heat exchange chamber 41, so as to prevent the coolant from directly impacting upward to the separator assembly 30 while refluxing.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A duo-pump liquid cooling device, comprising:
a base seat, comprising an inlet port, an outlet port, a concentrated cavity, a pair of accommodated grooves, a pair of channels, and an outlet groove, the inlet port communicated to the concentrated cavity, the outlet port communicated to the outlet groove, each of the accommodated grooves arranged in parallel and communicated to the concentrated cavity, each of the channels communicated to each of the accommodated grooves and located on two sides of the concentrated cavity;
a pair of pumps, configured to correspond to each of the accommodated grooves;
a separating assembly, wherein the concentrated cavity is located between the separating assembly and each of the accommodated grooves, the separating assembly covers the concentrated cavity and comprises a pair of through hole groups, a pair of diversion grooves, a through slot group, and a penetration hole, each of the through hole groups is communicated to the through slot group through each of the diversion grooves; and
a bottom seat, wherein the base seat is arranged on the bottom seat to form a heat exchange chamber and a pair of reflux cavities between the separating assembly and the bottom seat, each of the channels is communicated to the heat exchange chamber sequentially through each of the through hole groups, each of the diversion grooves, and the through slot group, the heat exchange chamber is communicated to each of the reflux cavities and communicated to the outlet groove through the penetration hole.

2. The duo-pump liquid cooling device according to claim 1, wherein the bottom seat comprises a plurality of fins arranged in parallel, a plurality of flow channels is formed between each two of the fins, each of the fins and the separating assembly together separate the heat exchange chamber to each of the flow channels and a pair of confluence areas, two ends of each of the flow channels are communicated to each of the reflux cavities through each of the confluence areas.

3. The duo-pump liquid cooling device according to claim 2, wherein each of the through hole groups is configured to be located at a diagonal corner the separating assembly.

4. The duo-pump liquid cooling device according to claim 2, wherein a location of the through slot group is located at a center of each of the fins.

5. The duo-pump liquid cooling device according to claim 1, wherein the separating assembly comprises a separating plate and a diversion plate, the separating plate is arranged between the base seat and the diversion plate and comprises each of the through hole groups, the diversion plate comprises each of the diversion grooves and is located between each of the through hole groups.

6. The duo-pump liquid cooling device according to claim 5, wherein the separating plate comprises a first partition plate and a second partition plate, the second partition plate is arranged between the first partition plate and the diversion plate, the penetration hole is defined on the first partition plate, a reflux gap is formed between the first partition plate and the second partition plate, each of the reflux cavities is communicated to the penetration hole through the reflux gap.

7. The duo-pump liquid cooling device according to claim 5, wherein the separating assembly further comprises an abutting sheet, the abutting sheet is arranged between the diversion plate and the bottom seat, the abutting sheet comprises a pair of limiting baffles, each of the limiting baffles is limited on two opposite sides of the diversion plate.

8. The duo-pump liquid cooling device according to claim 1, wherein the base seat comprises a main body and a mounting frame, the main body comprises the inlet port, the outlet port, the concentrated cavity, each of the accommodated grooves, each of the channels, and the outlet groove, the mounting frame comprises a pair of mounting grooves, is arranged on the main body, and covers each of the accommodated grooves, each of the mounting grooves is configured to correspond to each of the accommodated grooves.

9. The duo-pump liquid cooling device according to claim 8, wherein each of the pumps comprises a stator assembly and a rotor assembly, each of the rotor assemblies is arranged in each of the accommodated grooves, each of the stator assemblies is arranged in each of the mounting grooves.

10. The duo-pump liquid cooling device according to claim 1, wherein the inlet port and the outlet port are located on same side of the base seat.
